(19) United States
(12) Patent Application Publication
(10) Pub. No.: US 2009/0065816 A1
(43) Pub. Date: Mar. 12, 2009

(54) MODULATING THE STRESS OF POLY-CRYSTALINE SILICON FILMS AND SURROUNDING LAYERS THROUGH THE USE OF DOPANTS AND MULTI-LAYER SILICON FILMS WITH CONTROLLED CRYSTAL STRUCTURE

(75) Inventors: KEVIN L. CUNNINGHAM, Palo Alto, CA (US); Yi Ma, Santa Clara, CA (US); Majeed A. Foad, Sunnyvale, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: Applied Materials, Inc.

(21) Appl. No.: 12/206,390

(22) Filed: Sep. 8, 2008

Related U.S. Application Data
(60) Provisional application No. 60/971,364, filed on Sep. 11, 2007.

(51) Int. Cl. H01L 21/20; H01L 29/04; H01L 29/78

(52) U.S. Cl. 257/255; 438/482; 257/627; 257/E21.09; 257/E29.004; 257/E29.255

(57) ABSTRACT

In certain embodiments a method of forming a multi-layer silicon film is provided. A substrate is placed in a process chamber. An amorphous silicon film is formed on the substrate by flowing into the process chamber a first process gas comprising a silicon source gas. A polysilicon film is formed on the amorphous silicon film by flowing into the deposition chamber a first process gas mix comprising a silicon source gas and a first dilution gas mix comprising H₂ and an inert gas at a first temperature. In certain embodiments, the polysilicon film has a crystal orientation which is dominated by the <220> direction. In certain embodiments, the polysilicon film has a crystal orientation dominated by the <111> orientation. Structures comprising a lower amorphous silicon film and an upper polysilicon film having a random grain structure or a columnar grain structure are provided as well.

### CROSS-REFERENCE TO RELATED APPLICATIONS

This application claims benefit of U.S. Provisional Patent Application Ser. No. 60/971,364, filed Sep. 11, 2007, which is herein incorporated by reference.

### BACKGROUND OF THE INVENTION

1. Field of the Invention

Embodiments of the present invention generally relate to the field of semiconductor processing and more specifically to a multi-layer silicon film and methods of fabrication.

2. Description of the Related Art

Integrated circuits may include more than one million micro-electronic field effect transistors (e.g., complementary metal-oxide-semiconductor (CMOS) field effect transistors) that are formed on a substrate (e.g., semiconductor wafer). A CMOS transistor includes a gate structure that is disposed between a source region and a drain region defined in the semiconductor substrate. The gate structure generally comprises a gate electrode formed on a gate dielectric material. The gate electrode controls a flow of charge carriers, beneath the gate dielectric, in a channel region that is formed between the drain region and the source region, so as to turn the transistor on or off. The drain and source regions are collectively referred to in the art as a “transistor junction”. There is a constant trend to increase the operational speed and performance of such transistors.

Therefore, there is a need for a method for increasing the operational speed and performance of transistors.

### SUMMARY OF THE INVENTION

Embodiments described herein generally relate to methods of modulating stress in transistors by engineering the stress of silicon films used at or near the transistor. In one embodiment a method of forming a multi-layer silicon film is provided. A substrate is positioned in a process chamber. An amorphous silicon film is formed on the substrate by flowing into the process chamber a first process gas comprising a silicon source gas. A polysilicon film is formed on the amorphous silicon film by flowing into the deposition chamber a first process gas mix comprising a silicon source gas and a first dilution gas mix comprising H₂ and an inert gas at a first temperature. In certain embodiments, the polysilicon film has a crystal orientation which is dominated by the <220> direction. In certain embodiments, the polysilicon film has a crystal orientation dominated by the <111> orientation.

In another embodiment a gate electrode comprising a lower amorphous silicon film and an upper polysilicon film having a random grain structure or a columnar grain structure is provided. In certain embodiments, the upper polysilicon film has a grain size such that the vertical dimension is the same as the horizontal dimension. In certain embodiments the upper polysilicon film has a crystal orientation dominated by the <111> direction or orientation. In certain embodiments, the upper polysilicon film has a crystal orientation dominated by the <220> direction or orientation.

In yet another embodiment a MOS transistor is provided. The MOS transistor comprises a gate dielectric formed on a single crystalline silicon substrate, a gate electrode formed on the gate dielectric, and a pair of source/drain regions formed in the single crystalline substrate along opposite sides of the gate electrode. The gate dielectric comprises an amorphous silicon film and an upper polysilicon film. In certain embodiments, the upper polysilicon film of the MOS transistor is selected from the group comprising columnar poly-crystalline silicon, “MCG” poly-crystalline silicon, poly-crystalline silicon germanium, amorphous silicon, amorphous silicon germanium, and combinations thereof.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts an illustration of a cross-sectional side view of an exemplary semiconductor processing system;

FIG. 2 depicts an illustration of an enlarged view of an exemplary chamber and internal components of the chamber;

FIG. 3 depicts a process flow diagram of a deposition process in accordance with certain embodiments described herein;

FIG. 4A-4F depicts schematic cross-sectional views of a substrate structure in accordance with certain embodiments described herein;

FIG. 5 depicts a schematic cross-sectional view of a field effect transistor in accordance with certain embodiments described herein; and

FIG. 6 depicts a schematic plan view of an exemplary integrated semiconductor processing system (e.g. a cluster tool) of the kind used to practice certain embodiments described herein.

To facilitate understanding, identical reference numerals have been used, where possible, to designate identical elements that are common to the figures. It is contemplated that elements and/or process steps of one or more embodiments may be beneficially incorporated in one or more other embodiments without additional recitation.

### DETAILED DESCRIPTION

Embodiments described herein as recited in the claims generally relate to methods of modulating stress in NMOSFET and PMOSFET transistors by engineering the stress of silicon films used at or near the transistor. In some cases tensile stress improves the performance of NMOSFET, while in other cases, compressive stress improves the performance of PMOSFET. Stress causes the average distance between silicon atoms in the channel of the transistor to change. When the average distance between silicon atoms changes, the mobility of carriers (electrons and holes) is modulated. Therefore, the objective of stress engineering is to create tensile stress in the channels of NMOSFET while simultaneously creating compressive stress in the channels of PMOSFET. By engineering stress in the transistor channel the performance of the transistor may be improved.

Poly-crystalline silicon acts as a gate electrode which is formed directly on top of a gate dielectric. In turn, the gate dielectric is formed directly on top of the transistor channel in the single-crystal silicon upon which the gate dielectric is formed. Due to the proximity of the poly-crystalline silicon to the channel, small changes in the poly-crystalline silicon film stress have a large effect on the mobility of carriers in the channel of the transistor.

The stress of silicon films may be further modified by through the use of N-type dopants and P-type dopants. Typically, stress in poly-crystalline silicon films is compressive. Annealing poly-crystalline silicon films reduces the stress as the defects are annealed out of the film and as the poly-crystalline silicon grains grow larger. N-type dopants accelerate grain growth at a specific annealing temperature and further reduce stress and P-type dopants do not accelerate grain growth at a given annealing temperature to the same degree as N-type dopants. Further, after annealing, an NMOS transistor with N-type dopants in the poly-crystalline silicon gate electrode will have more tensile stress in the channel than a PMOS transistor with P-type dopants in the poly-crystalline silicon gate electrode. Thus, the stress difference between NMOS and PMOS as well as the total stress of PMOS and NMOS can be modulated not only by changing the grain structure of the poly-crystalline silicon but also by the use of dopants.

Although discussed with reference to poly-crystalline silicon used as a gate electrode, it should be understood that the techniques described herein are equally applicable to other parts of the transistor, including floating gates, plug conductor applications, and other structures.

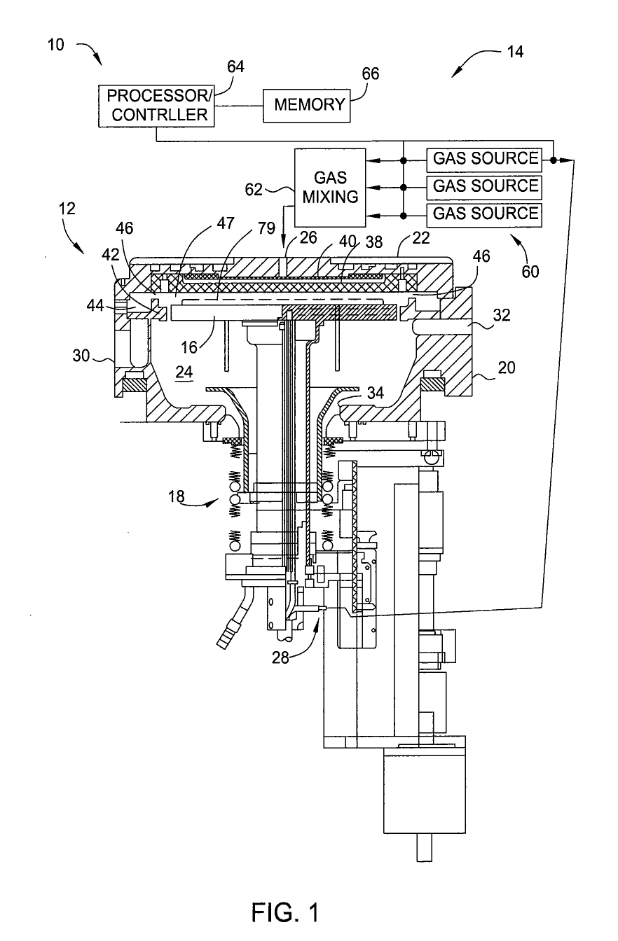

FIG. 1 is an illustration of a cross-sectional side view of an exemplary semiconductor processing system 10 in accordance with certain embodiments described herein. The system 10 includes a low-pressure chemical vapor deposition chamber 12, a gas supply apparatus 14, a susceptor 16, and a susceptor elevating apparatus 18. An example of a CVD chamber that may be used to deposit the materials described herein is a SiNgen® LPCVD chamber, available from Applied Materials, Inc. of Santa Clara, Calif.

The chamber 12 is a single-wafer deposition chamber. The chamber 12 is also a resistively heated single wafer deposition chamber. The chamber 12 can also be a cold-wall chamber in which a coolant fluid is supplied to a container (not shown) surrounding the wall of the chamber 12 to prevent the chamber 12 from getting too hot. With the reactant gases and the temperature in the range of 500° C. or 650° C. or even higher, being processed in the chamber 12, the chamber 12 may be easily corroded unless made out of a corrosion resistant material, which is often expensive. With the cold-wall feature, the chamber 12 does not need to be made out of such an expensive material that is corrosion resistant. The chamber 12 can be made out of an aluminum alloy or other suitable metal.

The chamber 12 includes a lower body 20 and a lid 22. The lid 22 seals peripherally with an upper extremity of the body 20. The body 20 and the lid 22 jointly define an inner volume 24 of approximately five to seven liters. A first gas inlet port 26 is formed through a center of the lid 22. A second gas inlet port 28 is formed into a base of the susceptor elevating apparatus 18 and leading directly into the bottom side of the chamber 12. A gas outlet port 30 is formed in a side of the body 20. The body 20 also has a slit valve opening 32 in one side thereof, and a susceptor elevating apparatus opening 34 in a base thereof.

A gas dispersion plate 38 or “shower head” is mounted below the lid 22. Surfaces of the lid 22 and the gas dispersion plate 38 jointly define a thin horizontal cavity 40. The gas dispersion plate 38 has a multitude of openings (not shown) formed therethrough that place the cavity 40 in communication with the inner volume 24.

A gas accumulation ring (or “pumping plate”) 42 is mounted within the chamber 12. The gas accumulation ring 42 and the surfaces of the chamber 12, define a ring volume 44. Gas outlet openings 46 are formed as an open gate between the pumping plate 42 and the dispersion plate 38. The ring volume 44 is in communication with the gas outlet port 30.

A process gas or gases can flow through the first gas inlet port 26 into the cavity 40. In certain embodiments, the process gas or gases may include a process gas mixture containing a silicon containing gas and an optional dopant source gas to form silicon film. The process gas or gases may also include other type of gas mixtures that will deposit other films on a substrate or otherwise treat or clean the substrate or clean the chamber 12. Gas then flows radially within the cavity 40. The gas or gases can then flow through the openings in the gas dispersion plate 38 into the inner volume 24. More process gas can enter through the second gas inlet port 28 into the inner volume 24. Typically, only a purging gas or an inert gas such as nitrogen (N₂) gas is introduced to the inlet port 28. The reactant gases are introduced through the inlet port 26. Introducing the inert gas through the inlet port 28 during the film deposition process prevents undesirable deposition on the bottom side of the chamber 12. The process gas or gases can exit the inner volume 24 through the gas outlet openings 46, be accumulated in the ring volume 44, and subsequently be pumped out through the gas outlet port 30.

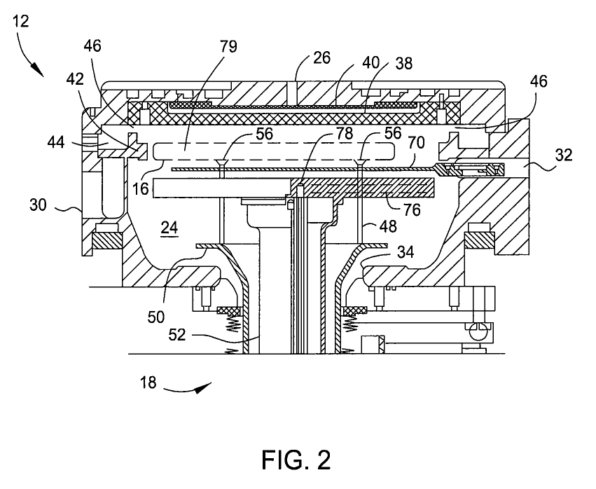

Referring to FIG. 2, the elevating apparatus 18 includes a set of elevating pins 48, a pin elevator 50, and a susceptor elevator 52. The pin elevator 50 and the susceptor elevator 52 are tubular members that extend through the apparatus opening 34 into the inner volume 24. The susceptor elevator 52 is, for the most part, located within the pin elevator 50. A portion of the susceptor elevator 52 extends out of an upper end of the pin elevator 50. A susceptor 16 is mounted to an upper end of the susceptor elevator 52. The susceptor is used to support a substrate 79 (shown in outline form in FIGS. 1 and 2). Vertical movement of the susceptor elevator 52 causes vertical movement of the susceptor 16.

The pins 48 extend through openings (not shown) in the susceptor 16. Each pin 48 has a head 56 at an upper end thereof. The pin elevator 50 engages with lower ends of the pins 48. Vertical movement of the pin elevator 50 causes vertical movement of the pins 48 relative to the chamber 12. The pins 48 also move relative to the susceptor 16, assuming that the susceptor 16 is stationary.

Referring again to FIG. 1, the gas supply apparatus 14 includes a gas bank 60 and a gas-mixing manifold 62. The gas supply apparatus 14 further couples to a processor/controller 64, and memory 66. The gas bank 60 has a number of different gas sources. The different gas sources may include silicon containing gas sources, carrier/dilution gas sources, and optional dopant gas sources. In one embodiment, the silicon containing gas sources include silane (SiH₄), disilane (Si₂H₆), and combinations thereof. In one embodiment, the gas sources include nitrogen gas (N₂), disilane (Si₂H₆) gas, and an optional dopant source gas, such as a phosphine (PH₃) gas. In certain embodiments, other carrier/dilution gases such as helium (He) gas, hydrogen (H₂) gas, nitrogen (N₂) gas, xenon (Xe) gas, and argon (Ar) gas can be included in the gas sources. Other dopant gas sources such as arsine (AsH₃), trimethylboron (TMB (or B(CH₃)₃)), diborane (B₂H₆), BF₃, B(C₂H₅)₃, and similar compounds. Each of the gas sources is connected through a respective valve (not shown) to the gas-mixing manifold 62. The gas-mixing manifold 62 is connected to the first gas inlet port 26. In certain embodiments, an inert gas such as an N₂ gas is also connected through a valve (not shown) to the second gas inlet port 28.

In certain embodiments, the processor/controller 64 controls operations of the gas bank 60. The processor/controller 64 is connected to the valves through which the gases can exit the gas bank 60 and enter the chamber 12. The processor/controller 64 can operate each valve independently so as to open or close flow from a respective gas source to either the gas-mixing manifold 62 or to the second gas inlet port 28. The memory 66 is connected to the processor/controller 64. A program or a set of instructions stored in the memory 66 and read by the processor/controller 64 can be used to control the operations of the gas bank 60. The valves can thus be opened or closed according to the instructions stored in the memory 66.

In certain embodiments, the processor/controller 64 also controls operations of the semiconductor processing system 10. For example, the processor/controller 64 executes a program stored in the memory 66 wherein the program further controls the process temperature (e.g., between 550° C. and 740° C.), process pressure (e.g., between 30 and 350 Torr), and the loading and unloading of a substrate into the chamber 12. In one embodiment, the program controls a flow ratio for the diluted dopant source gas and the disilane gas.

Referring to FIG. 2, when in use, a substrate 79 is located on a transfer blade 70 and then transported on the transfer blade 70 through the slit valve opening 32 into the inner volume 24 of the chamber 12. The substrate 79 can be inserted into the chamber 12 using a robot assembly.

To load a substrate (e.g., the substrate 79), the pin elevator 50 is raised so that the heads 56 make contact with a lower surface of the substrate, and lifts the substrate off the blade 70. The transfer blade 70 is then removed through the slit valve opening 32. The susceptor 16 remains stationary throughout this process. With the pin elevator 50 remaining stationary, the susceptor elevator 52 is then raised. Raising of the susceptor elevator 52 causes movement of the susceptor 16 in a vertically upward direction, while the pins 48 slide along the openings in the susceptor 16. The susceptor 16 is raised until an upper surface of the susceptor 16 makes contact with a lower surface of the substrate. The susceptor 16 is then further elevated until an upper surface of the substrate is at a required distance from the gas dispersion plate 38. In certain embodiments, the upper surface of the substrate is at a distance of approximately 14 mm from the gas dispersion plate 38.

In certain embodiments, a current is provided to a resistive heater 76 (see FIG. 2) located within the susceptor 16. In certain embodiments, the susceptor 16 can be made out of ceramic, graphite, aluminum, or other suitable material, preferably, ceramic. The current heats the resistive heater 76, and the heat conducts from the resistive heater 76 through the susceptor 16 to a substrate. In one embodiment, a thermocouple 78 (see FIG. 2) is located within the susceptor 16, and provides temperature feedback for purposes of controlling the temperature of the susceptor 16 and, indirectly, the temperature of the substrate. In certain embodiments, the temperature of the substrate is approximately 20° C. lower than the temperature measured at the susceptor 16.

In certain embodiments, the chamber 12 has a reacting space 47. The reacting space 47 is the area between the dispersion plate 38 and the susceptor 16. In certain embodiments, the reacting space 47 has a volume of about 750 cm³, which is the dispersion plate area times the distance between the dispersion plate 38 and the susceptor 16. In certain embodiments, the chamber 12 has an inner volume 24 of about 5 to 7 litters.

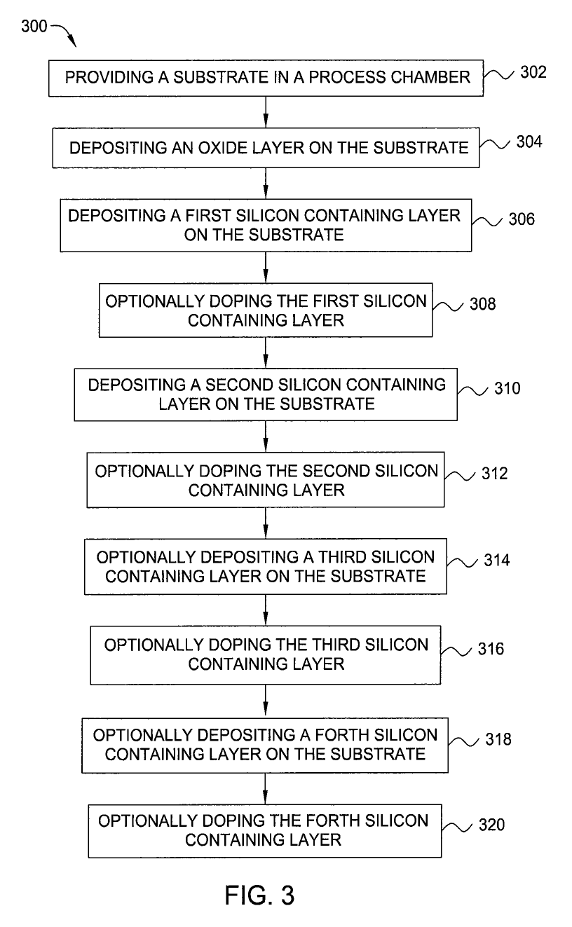

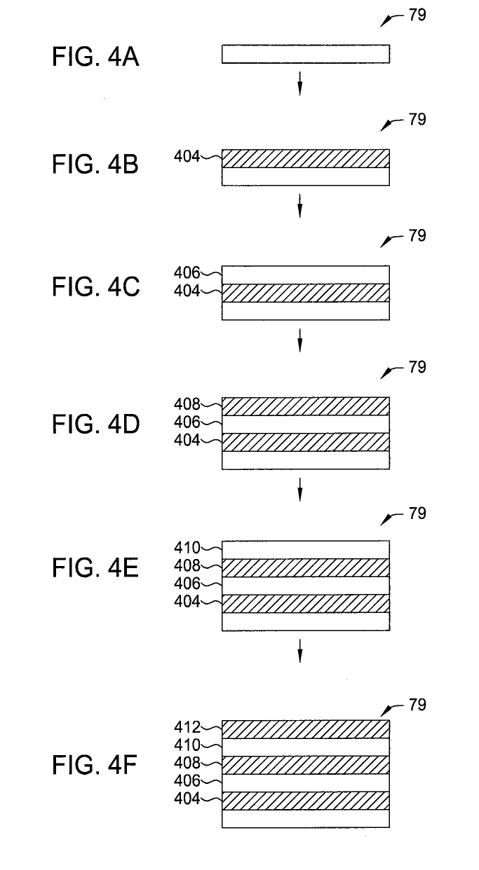

FIG. 3 depicts a process flow diagram of a deposition process according to certain described herein. It is also contemplated that the process 300 may be performed on other tools, including those from other manufacturers. FIG. 4A-4F depicts schematic cross-sectional views of a substrate structure in accordance with certain embodiments of the present invention.

The method 300 begins at step 302 by providing a substrate 79 to a processing chamber, such as processing chamber 12 which may be integrated into the system 600 described below. The substrate 79 refers to any substrate or material surface upon which film processing is performed. For example, the substrate 79 may be a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, sapphire or other suitable workpieces. The substrate 79 may have various dimensions, such as 200 mm, 300 mm diameter, or 450 mm wafers, as well as, rectangular or square panels. Unless otherwise noted, embodiments and examples described herein are conducted on substrates with a 200 mm diameter, a 300 mm diameter, or a 450 mm diameter. In certain embodiments, the substrate 79 may include an inter-poly dielectric film stack disposed thereon including a high-k material that may be suitable for non-volatile flash memory devices.

At step 304, an oxide layer is deposited on the substrate 79. The dielectric film stack disposed on the substrate 79 includes a gate oxide layer 404 disposed on the substrate 79. The gate oxide layer 404 may be deposited by any suitable process. In certain embodiments, the gate oxide layer 404 functions as a tunnel dielectric. In certain embodiments, the gate oxide layer 404 comprises silicon dioxide, silicon oxynitride (SiON), a nitrided oxide, or combinations thereof. The gate oxide layer 404 is generally deposited with a film thickness in a range from about 5 Å to about 30 Å, preferably from about 10 Å to about 25 Å, and more preferably from about 15 Å to about 20 Å.

Prior to transferring the substrate 79 into the processing chamber 12, a precleaning process may be performed to clean the substrate 79. The precleaning process is configured to cause compounds that are exposed on the surface of the substrate 79 to terminate in a functional group. Functional groups attached and/or formed on the surface of the substrate 79 include hydroxyls (OH), alkoxy (OR, where R=Me, Et, Pr or Bu), haloxyls (OX, where X=F, Cl, Br or I), halides (F, Cl, Br or I), oxygen radicals and aminos (NR or NR₂, where R=H, Me, Et, Pr or Bu). The precleaning process may expose the surface of the substrate 79 to a reagent, such as NH₃, B₂H₆, SiH₄, Si₂H₆, H₂O, HF, HCl, O₂, O₃, H₂O, H₂O₂, H₂, atomic-H, atomic-N, atomic-O, alcohols, amines, plasmas thereof, derivatives thereof or combinations thereof. The functional groups may provide a base for an incoming chemical precursor to attach on the surface of the substrate 79. In certain embodiments, the precleaning process may expose the surface of the substrate 79 to a reagent for a period from about 1 second to about 2 minutes. In certain embodiments, the exposure period may be from about 5 seconds to about 60 seconds. Precleaning processes may also include exposing the surface of the substrate 79 to an RCA solution (SC1/SC2), an HF-last solution, peroxide solutions, acidic solutions, basic solutions, plasmas thereof, derivatives thereof or combinations thereof. Useful precleaning processes are described in commonly assigned U.S. Pat. No. 6,858,547 and co-pending U.S. patent application Ser. No. 10/302,752, filed Nov. 21, 2002, published as US 2003-0232507, entitled, “Surface Pre-Treatment for Enhancement of Nucleation of High Dielectric Constant Materials,” which are both incorporated herein by reference in their entirety.

In certain embodiments where a wet-clean process is performed to clean the substrate surface, the wet-clean process may be performed in a TEMPEST™ wet-clean system, available from Applied Materials, Inc. Alternatively, the substrate 79 may be exposed to water vapor derived from a WVG system for about 15 seconds.

In certain embodiments, an inert gas such as nitrogen (N₂) gas is introduced into the chamber 12 at operation to equilibrate the chamber 12. The N₂ gas is introduced through the inlet ports 26 and 28. Through the gas inlet port 26, the N₂ gas is introduced into the top of the chamber 12 and in certain embodiments, with a flow rate of approximately 6000 standard cubic centimeters per minute (sccm). Through the gas inlet port 28, the N₂ gas is introduced into the bottom of the chamber 12 and in certain embodiments, with a flow rate of approximately 2000 sccm. In certain embodiments, the flow rates for the N₂ gas flowing through the inlet port 26 and 28 may a range from about 2000 sccm to about 10,000 sccm.

At step 306, a first silicon containing layer 406 is deposited on the substrate 79. The first silicon layer 406 may be selected from the group comprising columnar poly-crystalline silicon, “MCG” poly-crystalline silicon, poly-crystalline silicon germanium, amorphous silicon, amorphous silicon germanium, and combinations thereof. The first silicon containing layer 406 is generally deposited with a film thickness in a range from about 200 Å to about 3000 Å, preferably from about 500 Å to about 2000 Å, and more preferably from about 1000 Å to about 1500 Å.

In certain embodiments, the first silicon containing layer 406 is a columnar poly-crystalline silicon film. Columnar poly-crystalline silicon film is a polycrystalline silicon film having large columnar grains. The grains have vertical dimension to horizontal dimension of at least 2:1 and preferably at least 4:1. The crystal orientation of the columnar film is dominated by the <220> direction. The average grain size of the columnar grains are about 200-700 Å in the horizontal direction. The long columnar grain boundaries of the columnar film are generally perpendicular to the surface of the substrate.

A columnar grain silicon film can be formed by providing a process gas mix comprising a silicon source gas, such as but not limited to silane and a dilution gas into the chamber 12 while maintaining a pressure between 150-350 torr and heater temperature between 700-740° C. A columnar grain silicon film can be achieved by controlling the amount of H₂ (volume percent) included in the dilution gas of the second process gas mix. A suitable columnar grain silicon film can be formed by flowing into deposition chamber 12 a process gas mix comprising a silicon source gas and a dilution gas wherein the dilution gas comprises an inert gas (e.g., N₂, Ar, and He) and hydrogen gas (H₂) wherein H₂ comprises less than 8% by volume of the dilution gas mix and preferably less than 5% by volume of the dilution gas. In certain embodiments of the present invention, the columnar grain silicon film is formed with a process gas mix consisting only of a silicon source gas and a dilution gas consisting only of an inert gas and no H₂. A polycrystalline silicon film having columnar grains can be formed by flowing a process gas mix comprising between 50-150 sccm of silane (SiH₄) and between 10-30 slm of a dilution gas mix comprising less than 5% H₂ by volume, for example, from 1-5% H₂ by volume, and an inert gas while the pressure in chamber 12 is maintained between 150-350 torr and the temperature of the susceptor 16 maintained between 700-740° C.

In certain embodiments, the first silicon containing layer 406 is a “MCG” poly-crystalline silicon film. “MCG” poly-crystalline silicon is a polycrystalline silicon film having small and random grain boundary structure as opposed to a columnar grain structure. The “MCG” polycrystalline silicon film has an average grain size between 50-500 Å and has a vertical dimension which is approximately the same as the horizontal dimension. The “MCG” polycrystalline silicon film has a crystal orientation which is dominated by the <111> direction. The random grains and therefore grain boundaries of the “MCG” polycrystalline silicon film greatly reduces or slows down dopant diffusion within the film. The “MCG” polycrystalline silicon film can therefore be used to prevent dopant diffusion into underlying films, such as gate oxides.

“MCG” poly-crystalline silicon can be formed by providing a process gas mix comprising a silicon source gas and a dilution gas mix comprising H₂ and an inert gas is fed into chamber 12 to deposit a random grain polycrystalline silicon film on substrate 79. In the preferred embodiment described herein the silicon source gas is silane (SiH₄) but can be other silicon source gases such as disilane (Si₂H₆). According to the preferred embodiment described herein between 50-150 sccm, with between 70-100 sccm being preferred, of silane (SiH₄) is added to the dilution gas mix already flowing and stabilized during the temperature and pressure stabilization step. In this way during the deposition of random grain polysilicon, a process gas mix comprising between 50-150 sccm of silane (SiH₄) and between 10-30 slm of dilution gas mix comprising H₂ and an inert gas is fed into the chamber while the pressure in chamber 12 is maintained between 150-350 Torr and the temperature of susceptor 16 is maintained between 700-740° C. (It is to be appreciated that in the LPCVD chamber 12 the temperature of the substrate or wafer 79 is typically about 20-30° C. cooler than the measured temperature of the susceptor 16). In the preferred embodiment described herein the silicon source gas is added to the first component (upper component) of the dilution gas mix and flows into chamber 12 through inlet port 26. Methods for depositing “MCG” polycrystalline films are described in commonly assigned U.S. Pat. No. 6,726,955, issued Apr. 27, 2004, entitled METHOD OF CONTROLLING THE CRYSTAL STRUCTURE OF POLYCRYSTALLINE SILICON, which is herein incorporated by reference to the extent it does not conflict with the current specification.

In certain embodiments, the first silicon containing layer 406 is an amorphous silicon film. Amorphous silicon can be formed under a process pressure between 30 Torr and 350 Torr and a process temperature between 500° C. and 650° C. A process gas mixture comprising a silicon source gas such as silane or disilane gas and an inert gas is used to form the amorphous silicon layer. In certain embodiments, the silicon source gas is pure (not diluted) and is introduced into the chamber 12 at a relative flow rate ranging from 20 sccm to 200 sccm, and ideally, 60 sccm. The flow rate of the silicon source gas can be varied depending on the size of the chamber 12. In certain embodiments, the flow rate of the silicon source gas is selected for the chamber 12 that has the inner volume 24 with a volume between 5 and 7 liters and the reacting space 47 of about 750 cm³. Additionally, the relative flow rate of the silicon source gas can be varied depending on the desired thickness of the film. Generally, the relative flow rate of the silicon source gas is higher for a thicker film than for a thinner film.

In certain embodiments, the first silicon containing layer 406 is a silicon germanium alloy film. A silicon germanium alloy film (SiGe) may be formed with a silicon source gas comprising, for example, disilane and a germanium source gas comprising germane (GeH₄) at the same temperature utilized to deposit either the amorphous silicon film or the polycrystalline silicon film. A silicon germanium film having a thickness between 500-1000 Å may be formed. In one embodiment, an alloy having a ratio of silicon to germanium (Ge:Si) up to 1:1 can be formed. The Ge:Si ratio can be used to set the work function of the gate electrode.

Optionally, at step 308, the first silicon containing layer 406 is doped. The first silicon containing layer 406 may be doped either by an in-situ doping process or an ion implantation process.

In certain embodiments, a dopant gas mix is provided in the top portion of the chamber to in-situ dope the first silicon layer 406. In one exemplary embodiment, the dopant gas mix is phosphine (PH₃) diluted in hydrogen (H₂) or another dilutant and provided such that a pure phosphine flow rate of up to about 3 sccm can be provided. In certain embodiments, the dopant gas mix is diborane (B₂H₆) diluted in hydrogen (H₂) or another dilutant with a pure diboron flow rate of up to about 3 sccm. In certain embodiments, the dopant gas mix is arsine (AsH₃) diluted in hydrogen (H₂) or another dilutant with a pure arsine flow rate of up to about 3 sccm. The above described conditions can yield a doped polycrystalline or amorphous silicon film having a dopant concentration of up to about 10²¹ atoms per cubic centimeter. Typically, the dopant concentration is about 2×10¹⁹ to about 5×10²⁰ atoms per cubic centimeter.

In certain embodiments, the silicon containing layer 406 can be doped using ion-implantation. The silicon containing layer 406 may be doped while in blanket form over substrate 79 (i.e., prior to patterning) or after patterning into, for example, interconnects or electrodes. When forming a MOS transistor, it is preferable to ion-implant the silicon containing layer 406 after it has been patterned with well-known photolithography and etching techniques. In this way, the ion-implantation step is used to counter dope the substrate 79 to form source/drain regions. The implant can also be used to dope the gate electrode and thereby reduce resistivity. Following the optional doping step 308, the substrate 79 may be subjected to a thermal annealing process, such as, for example, rapid thermal annealing, spike annealing, millisecond annealing, or other thermal annealing processes.

Ion implantation of atoms other than silicon into the poly-crystalline silicon structure will change the average spacing between the atoms in the silicon crystalline lattice. This will cause the film to expand or contract, depending on the implanted atom size, which will cause stress in materials surrounding the poly-crystalline silicon. In the case of the gate electrode, the implantation of non-silicon atoms into the gate electrode poly-silicon would cause stress in the underlying transistor channel. For example, the implantation of atoms, which are larger than silicon, such as germanium, antimony, xenon, or indium into the poly-crsytalline silicon would increase the average spacing of the atoms in the crystalline lattice. The implantation of atoms, which are smaller than silicon, such as carbon, would decrease the average spacing of the atoms in the crystalline lattice. These non-silicon atoms also change the rate of grain growth which affects the final stress.

At step 310, a second silicon containing layer 408 is deposited on the substrate 79. The second silicon containing layer 408 may be selected from the group comprising columnar poly-crystalline silicon, “MCG” poly-crystalline silicon, poly-crystalline silicon germanium, amorphous silicon, amorphous silicon germanium, and combinations thereof. The second silicon containing layer 408 is generally deposited with a film thickness in a range from about 200 Å to about 3000 Å, preferably from about 500 Å to about 2000 Å, and more preferably from about 1000 Å to about 1500 Å. The second silicon containing layer 408 may be deposited using the techniques discussed above.

Optionally, at step 312, the second silicon containing layer 408 is doped. The second silicon containing layer 408 may be doped either by an in-situ doping process or an ion implantation process as discussed above. Following the optional doping step 312, the substrate 79 may be subjected to a thermal annealing process, such as, for example, rapid thermal annealing, spike annealing, millisecond annealing, or other thermal annealing processes.

Optionally, at step 314, a third silicon containing layer 410 is deposited on the substrate. The third silicon containing layer 410 may be selected from the group comprising columnar poly-crystalline silicon, “MCG” poly-crystalline silicon, poly-crystalline silicon germanium, amorphous silicon, amorphous silicon germanium, and combinations thereof. The third silicon containing layer 410 is generally deposited with a film thickness in a range from about 200 Å to about 3000 Å, preferably from about 500 Å to about 2000 Å, and more preferably from about 1000 Å to about 1500 Å. The third silicon containing layer 410 may be deposited using the techniques discussed above.

Optionally, at step 316, the third silicon containing layer 410 is doped. The third silicon containing layer 410 may be doped either by an in-situ doping process or an ion implantation process as discussed above. Following the optional doping step 316, the substrate 79 may be subjected to a thermal annealing process, such as, for example, rapid thermal annealing, spike annealing, millisecond annealing, or other thermal annealing processes.

Optionally, at step 318, a fourth silicon containing layer 412 is deposited on the substrate. The fourth silicon containing layer 412 may be selected from the group comprising columnar poly-crystalline silicon, “MCG” poly-crystalline silicon, poly-crystalline silicon germanium, amorphous silicon, amorphous silicon germanium, and combinations thereof. The fourth silicon containing layer 412 is generally deposited with a film thickness in a range from about 200 Å to about 3000 Å, preferably from about 500 Å to about 2000 Å, and more preferably from about 1000 Å to about 1500 Å. The fourth silicon containing layer 412 may be deposited using the techniques discussed above.

Optionally, at step 320, the fourth silicon containing layer 412 is doped. The fourth silicon containing layer 412 may be doped either by an in-situ doping process or an ion implantation process as discussed above. Following the optional doping step 320, the substrate 79 may be subjected to a thermal annealing process, such as, for example, rapid thermal annealing, spike annealing, millisecond annealing, or other thermal annealing processes. In certain embodiments, the substrate 79 may be annealed after all silicon containing layers have been deposited.

In a preferred bi-layer embodiment, the first silicon containing layer 406 is an amorphous silicon containing film and the second silicon containing layer 408 is a columnar polycrystalline film.

In another preferred bi-layer embodiment, the first silicon containing layer 406 is an amorphous silicon layer and the second silicon containing layer 408 is “MCG” polycrystalline film.

The use of multi-layer films and doping techniques to modulate stress in transistors may also be integrated into the process flow for CMOS transistor manufacturing. For example, there are several ways in which stress inducing ion-implantation may be used to modify the films in both NMOS and PMOS. In certain embodiments, one or more of the same types of non-silicon atoms are implanted into both NMOS and PMOS and the final stress of the films is modulated independently for both kinds of transistors to improve performance. In certain embodiments one or more non-silicon atoms are implanted into both NMOS and PMOS and the poly-crystalline silicon grain structure causes the final stress to be different for both NMOS and PMOS.

In certain embodiments the NMOS and PMOS are each implanted with different non-silicon atoms. For example, the poly-crystalline silicon gate electrode for NMOS is doped with the N-type dopant while the nearby PMOS is masked so that no N-type dopant reaches the PMOS poly-crystalline silicon. Correspondingly, non-silicon atoms could be implanted into the PMOS poly-crystalline silicon gate electrode right before, during, or directly after the P-type dopant implant while the NMOS poly-crystalline silicon gate electrode is masked.

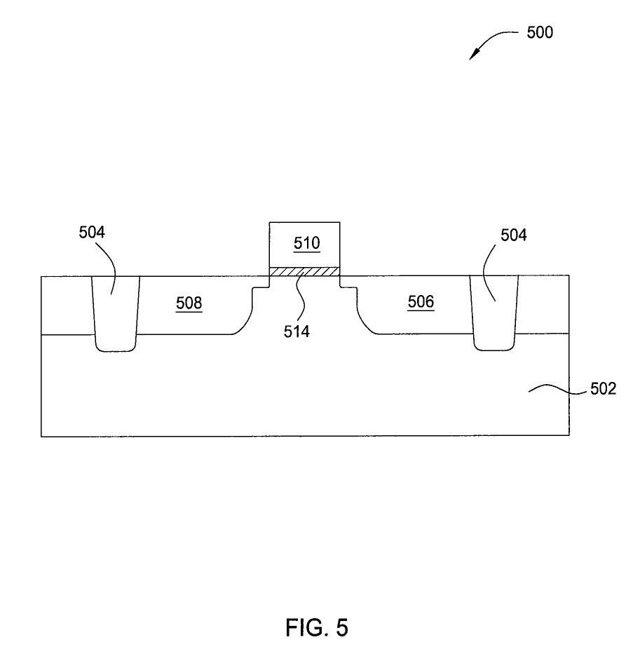

FIG. 5 depicts a schematic cross-sectional view of a field effect transistor in accordance with certain embodiments of the present invention. The substrate 502 has at least one partially formed semiconductor device 500 disposed thereon. Shallow trench isolations (STI) 504 are present to isolate each semiconductor device 500 formed on the substrate 502. One device 500 and two STI's 504 are shown in FIG. 5. A polysilicon gate electrode 510 is formed on a gate dielectric layer 514 disposed on the substrate 502 using the techniques described above. Source 508 and drain 506 regions are formed adjacent the gate dielectric 514 in the substrate 502 by ion implantation.

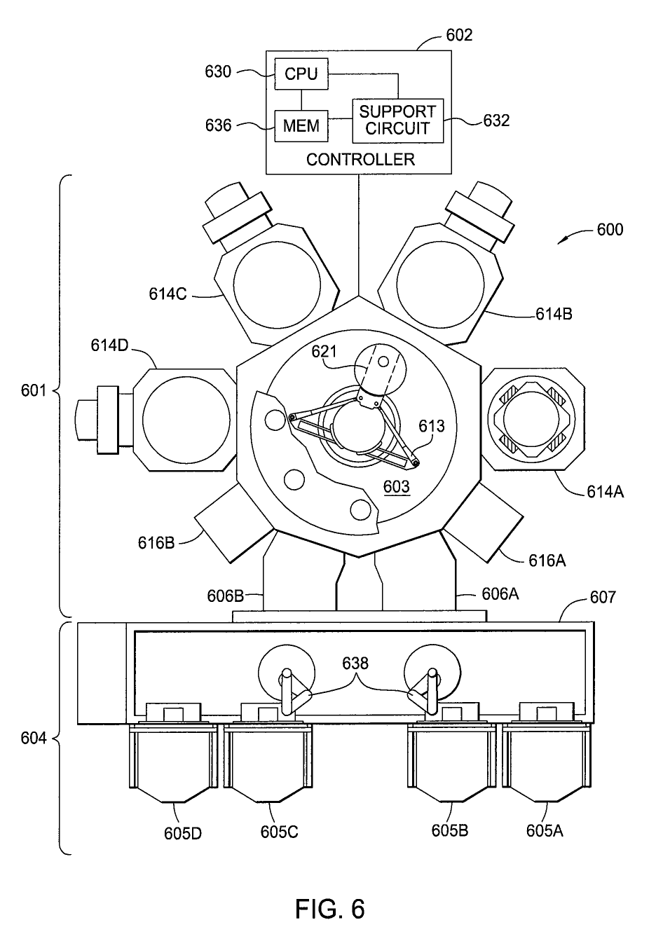

FIG. 6 depicts a schematic plan view of an exemplary integrated semiconductor processing system 600 of the kind used to practice certain embodiments of the present invention. Examples of the integrated system 600 include the PRODUCER®, CENTURA® and ENDURA® integrated tools, all available from Applied Materials, Inc., of Santa Clara, Calif. It is contemplated that the methods described herein may be practiced in other tools having the requisite process chambers coupled thereto, including those available from other manufacturers.

The tool 600 includes a vacuum-tight processing platform 601, a factory interface 604, and a system controller 602. The platform 601 comprises a plurality of processing chambers 614A-D and load-lock chambers 606A-B, which are coupled to a vacuum substrate transfer chamber 603. The factory interface 604 is coupled to the transfer chamber 603 by the load lock chambers 606A-B. The tool 600 includes a vacuum-tight processing platform 601, a factory interface 604, and a system controller 602. The platform 601 comprises a plurality of processing chambers 614A-D and load-lock chambers 606A-B, which are coupled to a vacuum substrate transfer chamber 603. The factory interface 604 is coupled to the transfer chamber 603 by the load lock chambers 606A-B.

In certain embodiments, the factory interface 604 comprises at least one docking station 607, at least one factory interface robot 638 to facilitate transfer of substrates. The docking station 607 is configured to accept one or more front opening unified pod (FOUP). Four FOUPS 605A-D are shown in the embodiment of FIG. 1. The factory interface robot 638 is configured to transfer the substrate from the factory interface 604 to the processing platform 601 for processing through the loadlock chambers 606A-B.

Each of the loadlock chambers 606A-B have a first port coupled to the factory interface 604 and a second port coupled to the transfer chamber 603. The loadlock chamber 606A-B are coupled to a pressure control system (not shown) which pumps down and vents the chambers 606A-B to facilitate passing the substrate between the vacuum environment of the transfer chamber 603 and the substantially ambient (e.g., atmospheric) environment of the factory interface 604.

The transfer chamber 603 has a vacuum robot 613 disposed therein. The vacuum robot 613 is capable of transferring substrates 621 between the loadlock chamber 606A-B and the processing chambers 614A-D. In certain embodiments, the transfer chamber 603 may include a cool down station built therein to facilitate cooling down the substrate while transferring a substrate in the tool 600.

In certain embodiments, the processing chambers coupled to the transfer chamber 603 may include chemical vapor deposition (CVD) chambers 614A-B, a Decoupled Plasma Nitridation (DPN) chamber 614C, and a Rapid Thermal Process (RTP) chamber 614D. The chemical vapor deposition (CVD) chambers 614A-B may include different types of chemical vapor deposition (CVD) chambers, such as a thermal chemical vapor deposition (Thermal-CVD) process, low pressure chemical vapor deposition (LPCVD), metal-organic chemical vapor deposition (MOCVD), plasma enhanced chemical vapor deposition (PECVD), sub-atmosphere chemical vapor deposition (SACVD) and the like. Alternatively, different processing chambers, including at least one ALD, CVD, PVD, DPN, or RTP chamber, may be interchangeably incorporated into the integrated tool 600 in accordance with process requirements. Suitable ALD, CVD, PVD, DPN, RTP, and MOCVD processing chambers are available from Applied Materials, Inc., among other manufacturers.

In certain embodiments, an optional service chamber (shown as 616A-B) may be coupled to the transfer chamber 603. The service chambers 616A-B may be configured to perform other substrate processes, such as degassing, orientation, pre-cleaning process, cool down, and the like.

The system controller 602 is coupled to the integrated processing tool 600. The system controller 602 controls the operation of the tool 600 using a direct control of the process chambers 614A-D of the tool 600 or alternatively, by controlling the computers (or controllers) associated with the process chambers 614A-D and tool 600. In operation, the system controller 602 enables data collection and feedback from the respective chambers and system to optimize performance of the tool 600.

While the foregoing is directed to embodiments of the present invention, other and further embodiments of the invention may be devised without departing from the basic scope thereof, and the scope thereof is determined by the claims that follow.

1. A method of forming a multi-layer silicon film comprising:
positioning a substrate in a deposition chamber;
forming an amorphous silicon film on the substrate by flowing into the deposition chamber a first process gas comprising a silicon source gas;
forming a polysilicon film on the amorphous silicon film by flowing into the deposition chamber a first process gas mix comprising a silicon source gas and a first dilution gas mix comprising H₂ and an inert gas at a first temperature.

2. The method of claim 1, wherein the first dilution gas mix comprises between 1-5% H₂ and the remainder inert gas.

3. The method of claim 1, wherein the first dilution gas mix comprises between 8-20% H₂ and the remainder inert gas.

4. The method of claim 1, wherein the polysilicon film has a crystal orientation which is dominated by the <220> direction or orientation.

5. The method of claim 1, wherein the polysilicon film has a crystal orientation which is dominated by the <111> direction or orientation.

6. The method of claim 1, further comprising:
forming a second polysilicon film on the first polysilicon film wherein the second polysilicon film is formed by flowing into the deposition chamber a second process gas mix including a silicon source gas and a second dilution gas mix, wherein the second dilution gas mix comprises H₂ and an inert gas at a second temperature, wherein the second temperature is greater than the first temperature.

7. The method of claim 1, further comprising:
forming a second polysilicon film on the first polysilicon film wherein the second polysilicon film is formed by flowing into the deposition chamber a second process gas mix including a silicon source gas and a second dilution gas mix, wherein the second dilution gas mix comprises H₂ and an inert gas at a second temperature, wherein the first temperature is greater than the second temperature.

8. The method of claim 1, wherein the forming an amorphous silicon film further comprises flowing a germanium source gas into the deposition chamber.

9. The method of claim 1, wherein the forming a polysilicon film on the amorphous silicon film comprises flowing a germanium source gas into the deposition chamber.

10. The method of claim 7, further comprising forming a third silicon film selected from the group consisting of columnar polycrystalline silicon, random grain polycrystalline silicon, amorphous silicon, polycrystalline silicon germanium, and amorphous silicon germanium.

11. A gate electrode comprising:
a lower amorphous silicon film; and
an upper polysilicon film having a random grain or columnar grain structure.

12. The electrode of claim 11, wherein the upper polysilicon film has a crystal orientation dominated by the <111> direction or orientation.

13. The electrode of claim 11, wherein the upper polysilicon film has a grain size such that the vertical dimension of the grain is much larger than the horizontal dimension.

14. The electrode of claim 11, wherein the upper polysilicon film has grain boundaries which have a vertical dimension to horizontal dimension of at least 2:1.

15. The electrode of claim 11, wherein the upper polysilicon film has grain boundaries which have a vertical dimension to horizontal dimension of at least 4:1.

16. The electrode of claim 11, wherein the upper polysilicon film has a crystal orientation which is dominated by the <220> direction or orientation.

17. The electrode of claim 11, further comprising a second polysilicon film deposited on the first polysilicon film.

18. The electrode of claim 17, wherein the second polysilicon film has a crystal orientation which is dominated by the <220> direction or orientation.

19. The electrode of claim 17, wherein the second polysilicon layer has a crystal orientation dominated by the <111> direction or orientation.

20. A MOS transistor comprising:
a gate dielectric formed on a single crystalline silicon substrate;
a gate electrode formed on the gate dielectric, the gate dielectric comprising:
an amorphous silicon film; and
an upper polysilicon film; and
a pair of source/drain regions formed in the single crystalline substrate along opposite sidewalls of the gate electrode, wherein the upper polysilicon film is selected form the group comprising columnar poly-crystalline silicon, “MCG” poly-crystalline silicon, poly-crystalline silicon germanium, amorphous silicon, amorphous silicon germanium, and combinations thereof.
